(19) United States
(12) Patent Application Publication
(10) Pub. No.: US 2005/0108874 A1
(43) Pub. Date: May 26, 2005

(54) Method of manufacturing capacitor-embedded printed circuit board (PCB)

(76) Inventors: Shin-Ki Lee, Gyeonggi-do (KR); Young-Joo Ko, Gyeonggi-do (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/971,197

(22) Filed: Oct. 25, 2004

(30) Foreign Application Priority Data
Nov. 21, 2003 (KR) 2003-0082902

(51) Int. Cl. H01L 21/44; H05K 1/02

(52) U.S. Cl. 29/849; 438/109; 438/106; 29/846; 174/259; 174/260

(57) ABSTRACT

A method of manufacturing a capacitor-embedded PCB is disclosed wherein a RCC with a resin thickness of several tens of micrometers and another RCC or a PREPREG with a copper foil is used for the embedded capacitor. The present invention eliminates the problem of losing a thermal pad of the upper electrode or the ground pad during the etching step of the outer layer. The present invention makes it possible to minimize the manufacturing tolerance due to the reduction of the beam size of a laser drilling and thereby to increase work efficiency.

### CROSS REFERENCE TO RELATED APPLICATION

This application claims priority under 35 USC §119 to Korean Patent Application No. 2003-82902, filed on Nov. 21, 2003, the contents of which are incorporated herein by reference in their entirety.

### FIELD OF THE INVENTION

The present invention relates to a capacitor-embedded printed circuit board (PCB), more particularly to a method of integrating a capacitor on the printed circuit board by employing a resin-coated copper (RCC) foil. The thickness of the resin of the RCC should be very thin down to 5-10 micrometer. The dielectric layer of the embedded capacitor consists of a copper-removed RCC foil and an additional insulating film such as another RCC or PREPREG with a copper film on top of it.

### BACKGROUND OF THE RELATED ART

Currently the PCB manufacturing industry employs a capacitor-embedded PCB technology because it provides a lower manufacturing cost as well as the failure rate of the production line. Furthermore, the capacitor-embedded PCB technology eliminates the technical problem such as noise generation (chattering noise) and sometimes the parasitic inductance effect observed at a node having a passive capacitor component because the passive component is connected to the nodes by lead molding.

Korean Patent No. 227,528 discloses the art for embedding a capacitor in a printed circuit board. Korean Patent No. 227,528 discloses a ZBC-2000 technique, which comprises staking an insulator with a thickness of 1-2 mils (25-50 micrometer) sandwiched with copper films as the upper and lower electrodes.

However, this technique has a shortcoming that the embedded capacitor implemented with epoxy resin as an insulator results in very poor capacitance. In order to resolve the issue of poor capacitance, the inventor of the present invention has proposed a technique of stacking a resin-coated copper (RCC) with a thickness of 1-2 mil resin film on the copper film in the Korean Patent Application 10-2002-0065114.

In the case when the bottom electrode functions as a clearance pad while the upper electrode being a thermal pad or a ground pad, the process comprises a step of selectively eliminating the copper foil of the RCC insulator with a photo-resist film after etching, and a laser drilling process for the formation of the clearance pad.

However, this still suffers from a technical problem that either the thermal pad of the upper electrode or the ground pad is simultaneously lost in the etching process. In order to avoid the above-mention problem, the engineers in the production line either manually differentiate the parts which need protection during the etching process or redesign the process sequence beforehand.

However, the solution disclosed in the previous paragraph is short-sighted and does not propose a fundamental solution because it can not be applicable to a large-size PCB having complicated manufacturing process steps. If the numbers of region that require special manual protection treatment during the etching process are numerous as in the case of a large-size PCB, then too much time is required to differentiate the critical parts, and consequently, the failure rate increases.

### SUMMARY OF THE INVENTION

A feature of the present invention is to provide a manufacturing method of a capacitor-embedded PCB for realizing a high capacitance value with minimized fabrication tolerance. Another feature of the present invention is to provide a manufacturing method of a capacitor-embedded PCB which protects a thermal pad or ground pad of an upper electrode from being lost during an etching process for eliminating the outer layer.

To accomplish the features of the present invention, a capacitor-embedded PCB employs a patterned RCC stacked with another RCC or PREPREG as a dielectric insulator. The present invention comprises steps of forming a patterned RCC on the inner layer, followed by eliminating the exposed copper with the patterned resin as a protective material. An inner stacked layer with resin on a surface is thereafter stacked either with another RCC or with PREPREG and copper foil.

### BRIEF DESCRIPTION OF THE DRAWINGS

FIGS. 1a through 1j are exemplary process flow for fabricating the capacitor-embedded PCB in accordance with the present invention.

### DETAILED DESCRIPTION OF THE INVENTION

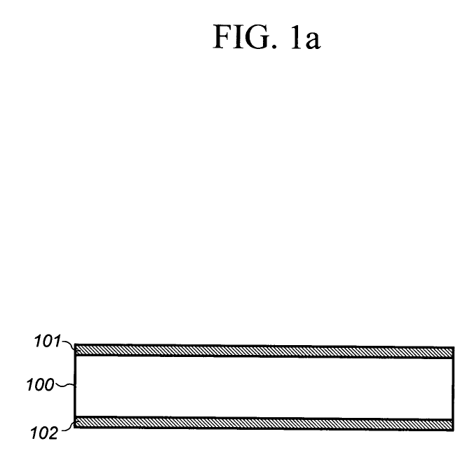

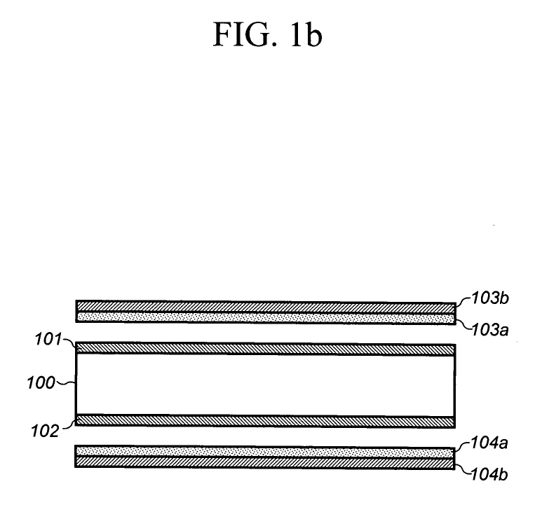

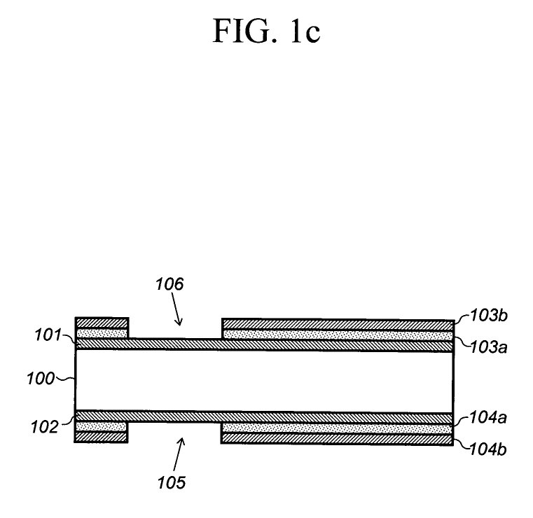

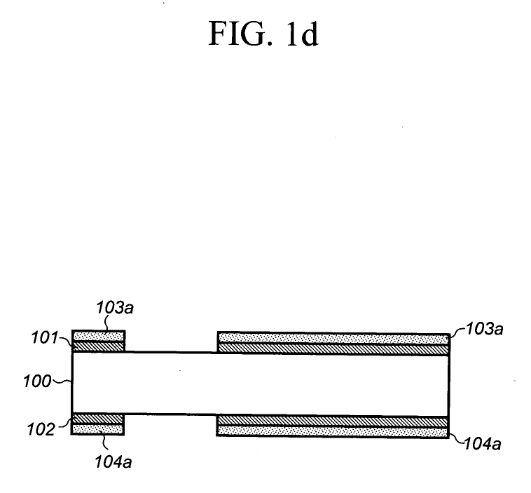

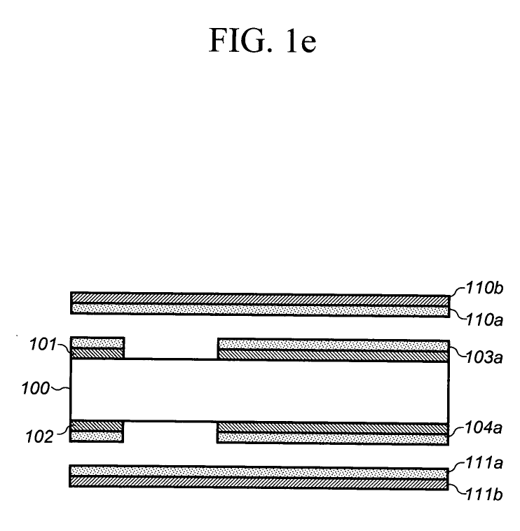

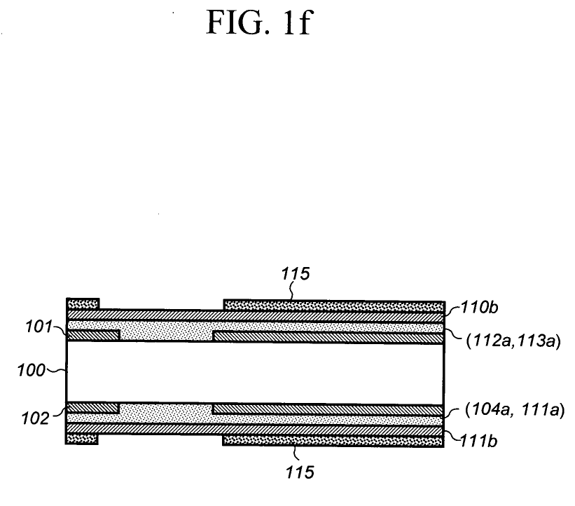

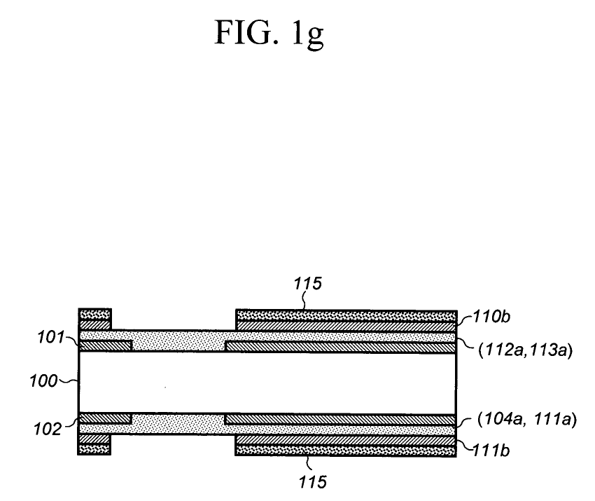

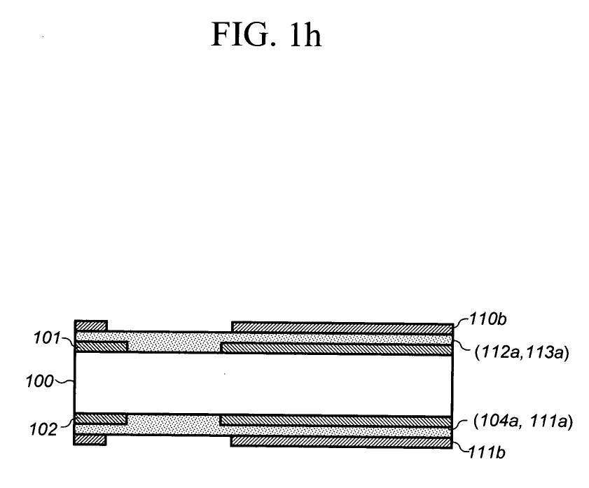

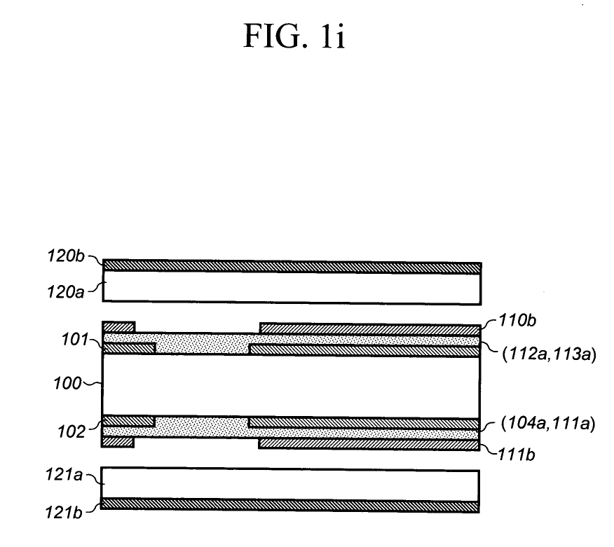

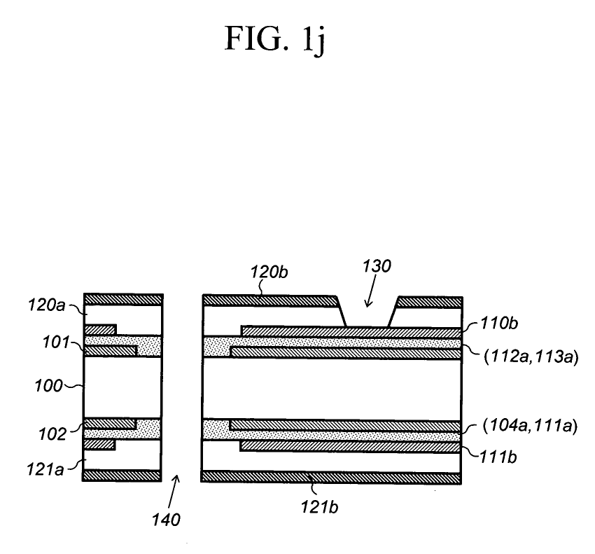

A manufacturing method of a capacitor-embedded PCB in accordance with the preferred embodiments of the present invention is explained with reference to FIGS. 1a through to 1j, which illustrates the process flow. Referring to FIG. 1a, a stacked layer with an inner insulating layer 100 sandwiched by a first upper 101 and lower 102 copper foils is illustrated. As a preferred embodiment of the inner insulating layer 100, an epoxy or a glass fiber can be utilized.

Referring to FIG. 1b, very thin first resin layers 103a, 104a sandwich the inner stacked layers 100, 101, 102. Here, the thickness of first resin layers 103a, 104a can be in the range of 5-10 micrometer, and RCC can be employed as a preferred embodiment. In the present invention, the deviation of the thickness of the deposited resin can be minimized because the thin first resin layers 103a, 104a is entirely covered with a copper layer.

Referring to FIG. 1c, copper film holes 105, 106 are patterned and followed by removing portions of the first resin layers 103a, 104a with a laser-drilling. Here, the laser-drilling can be performed with a beam with large spot diameter in comparison to the thickness of the first resin layers 103a, 104a (5-10 micrometer).

As a preferred embodiment in accordance with the invention, the spot diameter size can be several millimeters (mm) in diameter. Further, the difference in the length between the upper and lower surface of the laser-patterned insulating film is minor, which is due to the fact that the insulating film is very thin. In other words, because the length between the removed upper and lower first resin layers 103a, 104a is almost the same, the bottom electrode can be formed without appreciable manufacturing tolerance.

As a consequence, the tolerance of the capacitance can be minimized. Furthermore, the present invention makes it possible to increase the spot diameter size up to several millimeters in diameter which in turn enhances the efficiency of the manufacturing process. For example, it is expected that more than 10-50 times working efficiency can be achieved when comparing the bean spot size of 100-400 micrometers (μm) employed in the current manufacturing technology.

Referring to FIG. 1c again, when the bottom electrode is a clearance pad and the upper electrode is a thermal pad or a ground pad, for example, the upper electrode is lost during an etching process. Referring to FIG. 1d, second copper foils 103b, 104b of the RCC are selectively removed with an etching resist. In this case, it should be noted a dry film or an etching resist is not needed.

Referring to FIG. 1e, RCC or PREPREG, i.e., second resin layers 110a, 111a with third copper foils 110b, 111b are then secondarily stacked. Thereafter, as shown in FIG. 1f, the third copper foils 110b, 111b are selectively protected with an etching resist 115.

Referring to FIGS. 1g and 1h, the portions of the third copper foils 110b, 111b are removed, and thereafter the etch resist 115 is removed. As a consequence, a capacitor dielectric layers 112a, 113a are formed between the electroplates, i.e., third upper copper foil and first upper copper foil 110b, 101, respectively. Referring to FIG. 1i, either RCC or PREPREG, i.e., third resin layers 120a, 121a with fourth copper foils 120b, 121b is deposited on the inner stacked capacitor. A blind via hole 130 and through hole 140 process (FIG. 1j) are followed.

The forgoing embodiments are merely exemplary and are not to be construed as limiting the present invention. The present teachings can be readily applied to other types of processes. The description of the present invention is intended to be illustrative, and not to limit the scope of the claims. Many alternatives, modifications, and variations will be apparent to those skilled in the art. Although the invention has been illustrated and described with respect to exemplary embodiments thereof, it should be understood by those skilled in the art that various other changes, omissions and additions may be made therein and thereto, without departing from the spirit and scope of the present invention. Therefore, the present invention should not be understood as limited to the specific embodiment set forth above but to include all possible embodiments which can be embodied within a scope encompassed and equivalents thereof with respect to the feature set forth in the appended claims.

1. A method of manufacturing a capacitor-embedded PCB comprising steps of:
forming an inner stacked layer comprising a first copper foil and a first insulating layer;
providing a first stacked layer comprising a first resin layer and a second copper foil on the inner stacked layer, wherein the first resin layer is formed on the first copper foil;
forming an opening in the first stacked layer to expose a portion of the first copper foil;
removing the second copper foil;
etching the exposed portion of the first copper foil using the first resin layer as an etching mask to expose a portion of the first insulating layer;
providing a second stacked layer comprising a second resin layer and a third copper foil, wherein the second resin layer contacts the first resin layer; and
forming a resist pattern on the third copper foil, wherein the an opening in the resist pattern is aligned over the exposed portion of the first insulating layer.

2. The method of claim 1 further comprising steps of:
exposing a portion of the third copper foil using the resist pattern as a mask;
removing the resist pattern;
providing a third stacked layer comprising a third resin layer and a fourth copper foil, wherein the third resin layer contacts the third copper foil;
forming a via hole in the resulting structure through a section where openings in the first insulating layer and the third cooper foil layer used to be; and
forming an opening to expose a portion of the third copper foil.

3. The method of claim 1, wherein the manufacturing steps are mirrored on both upper and lower sides of the inner stacked layer.

4. The method of claim 2, wherein the manufacturing steps are mirrored on both upper and lower sides of the inner stacked layer, except for the steps of forming the via hole and the opening to expose the portion of the third copper foil.

5. The method of claim 1, wherein the first and second resin layers have a thickness about 5-10 micrometers.

6. The method of claim 2, wherein the third resin layer has a thickness about 5-10 micrometers.

7. The method of claim 1, wherein the first resin layers layer is a resin coated copper foil.

8. The method of claim 1, wherein the second resin layer is a resin coated copper foil or a PREPREG.

9. The method of claim 2, wherein the third resin layer is a resin coated copper foil or a PREPREG.

10. The method of claim 1, wherein forming the opening in the first stacked layer to expose the portion of the first copper foil is by a laser drilling.

11. The method of claim 10, wherein a spot diameter size of the laser drilling is about 1-10 mm.
